(19) United States
(12) Patent Application Publication
(10) Pub. No.: US 2013/0175680 A1
(43) Pub. Date: Jul. 11, 2013

(54) DIELECTRIC MATERIAL WITH HIGH MECHANICAL STRENGTH

(71) Applicants: Stephen M. Gates, Ossining, NY (US); Alfred Grill, White Plains, NY (US); Errol T. Ryan, Clifton Park, NY (US)

(72) Inventors: Stephen M. Gates, Ossining, NY (US); Alfred Grill, White Plains, NY (US); Errol T. Ryan, Clifton Park, NY (US)

(73) Assignee: INTERNATIONAL BUSINESS MACHINES CORPORATION, Armonk, NY (US)

(21) Appl. No.: 13/347,687

(22) Filed: Jan. 10, 2012

(51) Int. Cl. H01L 23/532; C07F 7/18; H01L 21/314

(52) U.S. Cl. 257/734; 438/786; 556/435; 257/E23.167; 257/E21.266

(57) ABSTRACT

A multiphase ultra low k dielectric process is described incorporating a first precursor comprising at least one of carbosilane and alkoxycarbosilane molecules containing the group Si—(CH₂)ₙ—Si where n is an integer 1, 2 or 3 and a second precursor containing the group Si—R* where R* is an embedded organic porogen, a high frequency radio frequency power in a PECVD chamber and an energy post treatment including ultraviolet radiation. An ultra low k porous SiCOH dielectric material having at least one of a k in the range from 2.2 to 2.3, 2.3 to 2.4, 2.4 to 2.5, and 2.5 to 2.55 and a modulus of elasticity greater than 5, 6, 7.8 and 9 GPa, respectively and a semiconductor integrated circuit comprising interconnect wiring having porous SiCOH dielectric material as described above.

### BACKGROUND

The present invention relates to a process for forming multiphase ultra low k dielectric material and more particularly to a plasma enhanced chemical vapor deposition (PECVD) process utilizing a first and second precursor and an energy post treatment of ultra violet radiation to form porous SiCOH having a k lower than 2.55 and a modulus of elasticity greater than or equal to 5 GPa.

### BRIEF SUMMARY OF THE INVENTION

In accordance with the present invention, a method for forming an ultra low k dielectric layer is described comprising selecting a plasma enhanced chemical vapor deposition reactor; placing a substrate in the reactor; introducing a gas mixture flow into the reactor; the gas mixture comprising an inert carrier gas, a first precursor gas comprising at least one of a carbosilane and alkoxycarbosilane molecules comprising atoms of Si, C, O and H and containing the group Si—(CH₂)ₙ—Si where n is an integer 1, 2 or 3 and a second precursor gas containing the group Si—R* comprising atoms of Si, C, O and H and where R* is an embedded organic porogen; heating the substrate to a temperature above 100° C.; forming a deposited layer by applying high frequency radio frequency power in the reactor; after a period of time terminating the high frequency radio frequency power in the reactor; and applying to the deposited layer an energy post treatment comprising ultra violet (UV) radiation to drive out the embedded organic porogen, create porosity in the deposited layer and increase cross-linking in the deposited layer.

This invention also provides a porous SiCOH dielectric material having a tri-dimensional random covalently bond network of Si—O, Si—C, Si—(CH₂)ₙ—Si where n is an integer 1, 2 or 3, C—O, Si—H, and C—H bonds, and one of a dielectric constant k in the range from 2.2 to 2.3 and a modulus of elasticity greater than or equal to 5 GPa, a k in the range from 2.3 to 2.4 and a modulus of elasticity greater than 6 GPa, a k in the range from 2.4 to 2.5 and a modulus of elasticity greater than 7.8 GPa, and a k in the range from 2.5 to 2.55 and a modulus of elasticity in the range from 9 to 15 GPa.

This invention further provides a semiconductor integrated circuit comprising an interconnect wiring having a porous SiCOH dielectric material having a tri-dimensional random covalently bond network of Si—O, Si—C, Si—(CH₂)ₙ—Si where n is an integer 1, 2 or 3, C—O, Si—H, and C—H bonds having one of a dielectric constant k in the range from 2.2 to 2.3 and a modulus of elasticity greater than or equal to 5 GPa, a k in the range from 2.3 to 2.4 and a modulus of elasticity greater than 6 GPa, a k in the range from 2.4 to 2.5 and a modulus of elasticity greater than 7.8 GPa, and a k in the range from 2.5 to 2.55 and a modulus of elasticity in the range from 9 to 15 GPa.

### BRIEF DESCRIPTION OF THE SEVERAL VIEWS OF THE DRAWINGS

These and other features, objects, and advantages of the present invention will become apparent upon consideration of the following detailed description of the invention when read in conjunction with the drawing in which:

FIG. 1 is a graph of Fourier Transform Infrared (FTIR) spectrum obtained from three PECVD deposited multiphase porous SiCOH films in which the marked absorbance peak at 1360 cm⁻¹ of Si—CH₂—Si bonds is shown having respective values.

FIG. 2 shows an expanded portion of FIG. 1 with changes in the scale of the ordinate and the abscissa.

FIG. 3 is a cross-section view of an embodiment of the invention showing a patterned metal conductor within a dielectric layer of this invention in a semiconductor integrated circuit or chip.

### DETAILED DESCRIPTION

An ultra low k dielectric layer may be formed in a plasma enhanced chemical vapor deposition (PECVD) reactor by placing a substrate in the reactor and introducing into the reactor a gas mixture comprising an inert carrier gas such as He or Ar, a first precursor gas (vapor) comprising at least one of carbosilane and alkoxycarbosilane molecules comprising atoms of Si, C, O and H and containing the group Si—(CH₂)ₙ—Si where n is an integer 1 or greater and a second precursor gas (vapor) containing the group Si—R* comprising atoms of Si, C, O and H and where R* is an embedded organic porogen.

A first precursor gas may be selected from the group consisting of bis(triethoxysilyl)methane, bis(diethoxymethylsilyl)methane, bis(trimethoxysilyl)methane and bis(dimethoxymethylsilyl)methane molecules.

Second precursor gas may be selected from the group consisting of a Si based precursor with at least one group R* bonded to Si selected from group consisting of n-butyl, n-propyl, iso-propyl, vinyl, and alkyl, alkene and alkyne groups containing 2, 3 or 4 carbon atoms. In an alternate embodiment, second precursor gas may be selected from the group consisting of a Si based precursor with at least one group R* bonded to Si with R* containing 5 to 10 carbon atoms bonded in a linear, branched, monocyclic or bicyclic structure. In other alternate embodiments, the group R* may include one or more oxygen atoms. Generally, second precursor gas may also comprise at least one group bonded to the above Si selected from the group consisting of methoxy, ethoxy, methyl, ethyl, propoxy and related alkoxy molecules or groups

The parameters of the PECVD reactor may be adjusted as known in the art, the parameters include pressure, substrate temperature, spacing between substrate and a gas distribution plate, and flow rate of the gas mixture. The pressure in the reactor may be controlled to be in the range from 5 to 9 Torr. and preferably about 7 Torr. The substrate may be heated to a temperature in the range from 100° C. to 350° C. and preferably heated in the range from 200° C. to 300° C. The substrate may be a Si wafer and may contain partially constructed digital circuits such as logic circuits, memory circuits, and other electronic structures comprising one or more bipolar transistors, field effect transistors, charge coupled devices, capacitors, inductors, diodes and interconnect wiring.

A dielectric layer is formed on the substrate by applying high frequency radio frequency power in the PECVD reactor. The high frequency power may be at or greater than 400 kHz, for example 13.56 MHz. Other frequency power sources may also be used within the invention. By setting the high frequency radio frequency power just above plasma initiation, an increase in polymerization occurs and an increase in retention of a sacrificial organic porogen in the deposited dielectric layer occurs. Further by the above setting, minimum plasma dissociation of a sacrificial organic porogen or functional group occurs in the plasma and cross-linking of large molecules occur to form the deposited dielectric layer with a high degree of porosity greater than or equal to 13.8 volume percent after an energy post treatment.

An additional gas is selected from the group consisting of a reactive oxidant gas and an oxygenated hydrocarbon gas and introduced into the PECVD reactor to stabilize the plasma in the reactor and improve the properties and uniformity of the deposited dielectric layer. The reactive oxidant gas may be selected from the group consisting of O₂, N₂O, CO₂ and combinations thereof.

The growth of the dielectric layer is stopped or terminated by lowering or turning off the high frequency radio frequency power in the PECVD reactor.

The as-deposited dielectric layer may be subjected to an energy post treatment of ultra violet radiation for a selected time period at a dielectric layer temperature above 200° C. to increase Si—(CH₂)ₙ—Si cross linking bonds where n is an integer 1, 2 or 3 in the dielectric layer. The time period of said energy post treatment may be from 100 to 1000 seconds, for example, and other times may be used within the invention. The as-deposited dielectric layer typically has two adjacent Si—CH₃+Si—CH₃ chemical bonding groups which change to Si—(CH₂)ₙ—Si bonds to increase the modulus of elasticity and hardness of the dielectric layer and a volatile CH₄ will outgas. The outgas of volatile CH₄ creates additional pores in the deposited dielectric layer. The energy post treatment thermal anneal may include heating the as-deposited dielectric layer to a temperature in the range from 200° C. to 430° C. in an ambient of forming gas (H₂ and N₂) for a period of time greater than 40 minutes. The dielectric layer after energy post treatment may have a tri-dimensional random covalently bond network of Si—O, Si—C, C—H₃, Si—(CH₂)ₙ—Si where n is an integer, C—O, Si—H and C—H bonds, and one of a dielectric constant k in the range from 2.2 to 2.3 and a modulus of elasticity greater than or equal to 5 GPa, a k in the range from 2.3 to 2.4 and a modulus of elasticity greater than 6 GPa, a k in the range from 2.4 to 2.5 and a modulus of elasticity greater than 7.8 GPa, and a k in the range from 2.5 to 2.55 and a modulus of elasticity in the range from 9 to 15 GPa. A fraction X of the C atoms in a layer are covalently bonded in the functional group Si—(CH₂)ₙ—Si. The modulus of elasticity in the dielectric layer is uniform in all directions or isotropic.

The as-deposited dielectric layer characteristics for the dielectric layer change after an energy post treatment of ultra violet radiation. The wavelength of UV may be a narrow spectrum or a broad spectrum. Certain wavelengths of UV enhance specific reactions. The dielectric layer after an energy post treatment has a dielectric constant (k value) in the range from 2.2 to 2.55, measured at 150° C. in a metal-insulator-semiconductor (MIS) structure with aluminum electrodes as the metal and Si wafer substrate as the semiconductor. The dielectric layer after an energy post treatment has a volume % porosity in the range from 15 to 35 volume percent, and a pore diameter in the range from 0.5 to 1.5 nm, with 1.0 nm being a typical value, as measured by Ellipsometric porosimetry (EP) with a toluene absorbent. The dielectric layer after an energy post treatment has a modulus of elasticity in the range from 5 to 15 GPa, measured by nanoindentation. The dielectric layer after an energy post treatment has a carbon content in the range from 10 to 30 atomic percent, an oxygen content in the range from 40 to 55 atomic percent, and a silicon content in the range from 30 to 40 atomic percent, measured by X-ray photoelectron spectroscopy (XPS). The measured k value, modulus, volume % porosity and atomic percent of C, Si and O measured by XPS are shown in Table I embodiments 1, 2 and 3 of the inventive material after the energy post treatment of ultra violet radiation at approximately 400° C.

TABLE I

| EMBODIMENTS | 1 | 2 | 3 |
|---|---|---|---|
| k value at 150° C., MIS | 2.55 | 2.4 | 2.3 |
| Modulus (Gpa) | 10.4 | 8.0 | 6.1 |
| Porosity (volume %) | 21.0 | 23.3 | 29.3 |
| C % (XPS) | 17 | 13 | 16 |
| Si % (XPS) | 34 | 36 | 34.4 |
| O % (XPS) | 49 | 50 | 49.6 |

Other energy post treatment besides UV radiation may be thermal anneal and electron beam (EB) irradiation. Thermal anneal treatment is especially applicable where a dielectric layer is vertical such as if used as a gate stack sidewall spacer on a field effect transistor or if portions of the layer are vertical and other portions are horizontal. UV radiation and EB irradiation may provide an uneven exposure to a vertical dielectric layer. Energy post treatment functions to drive out the organic porogen and to increase the porosity in the deposited dielectric layer. The dielectric layer may have a dielectric constant lower than 2.55 and a modulus of elasticity in the range from 5 to 15 GPa.

The porous SiCOH dielectric material of the present invention has more carbon bonded in organic groups bridging between two Si atoms, for example, Si—(CH₂)ₙ—Si where n is an integer 1, 2 or 3 compared to prior art SiCOH and pSiCOH dielectrics prepared by PECVD using other organic precursors. Three SiCOH dielectric layers on respective substrates have been subjected to Fourier transform infrared (FTIR) spectroscopy to determine the extent of carbon bonding in Si—(CH₂)n—Si where n is an integer. The FTIR spectroscopy for Si—CH₂—Si has an absorbance peak centered at 1360 cm−1. A value for the absorbance peak can be determined by integrating the area under the waveform associated with the peak at 1360 cm−1 and then dividing by the dielectric layer thickness, where thickness is measured in microns. The ratio of the absorbance peak area of the porous SiCOH dielectric material of the present invention where k is equal to 2.4 to the FTIR absorbance peak area of the SiCOH dielectric material of the prior art is approximately 2. The area of the FTIR absorbance peak at 1360 cm−1 of porous SiCOH dielectric material where k is 2.4 is approximately 2 times greater than the area of the FTIR absorbance peak at 1360 cm−1 of the SiCOH dielectric material of the prior art.

The area of the FTIR absorbance peak at 1360 cm−1 of porous SiCOH dielectric layer where k is 2.55 is approximately 3 times greater than the area of the FTIR absorbance peak at 1360 cm−1 of the SiCOH dielectric material of the prior art. The greater area of the FTIR absorbance peak at 1360 cm−1 between dielectric materials is indicative of the organic group CH₂ bridging between two Si atoms in the form Si—(CH₂)ₙ—Si, with n=1 in this specific example.

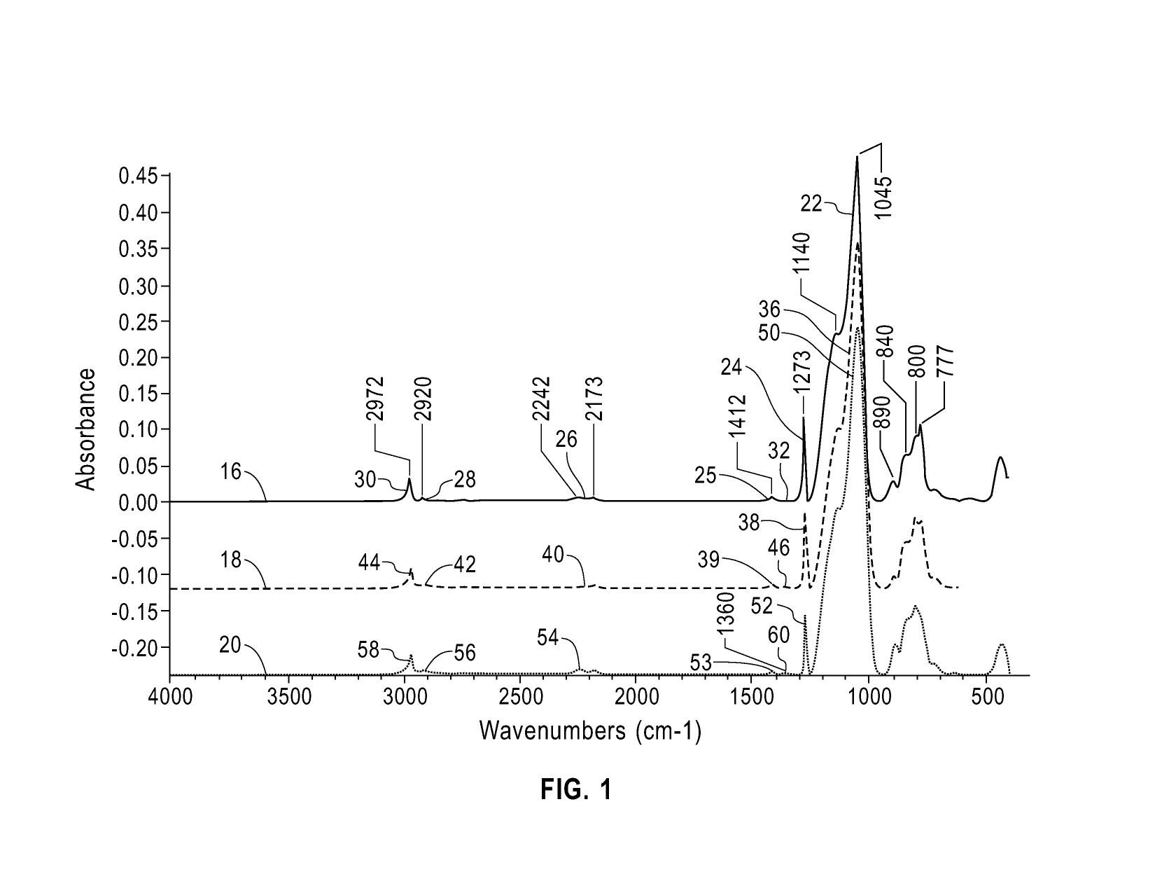

FIG. 1 is a graph of FTIR spectrum shown by curves 16, 18 and 20 obtained from three deposited dielectric layers after energy post treatment formed on separate respective substrates. Curve 16 was obtained from a first dielectric layer of porous ultralow k SiCOH of the prior art. Curve 18 was obtained from a second dielectric layer of porous ultralow k SiCOH of high carbon percentage in Si—CH₂—Si bonds using other organic precursors. Curve 20 was obtained from a third dielectric layer of porous ultralow k SiCOH formed by the inventive process herein.

In FIG. 1 the ordinate represents Absorbance and the abscissa represents Wave numbers (cm⁻¹). Referring to curve 16 in FIG. 1, the spectrum displays a strong Si—O absorption band 22 at 975-1200 cm⁻¹ with an absorbance of 0.485, a Si—CH₃ absorption peak 24 at 1273 cm⁻¹ with an absorbance of 0.125, a Si—Meₓ absorption peak 25 at 1412 cm−1 with an absorbance of 0.06, a Si—H absorption band 26 at 2173-2242 cm⁻¹ with an absorbance of 0.005, and C—H absorption peaks 28 and 30 at 2920-2972 cm⁻¹ with a respective absorbance of 0.002, and 0.029. The marked absorbance peak 32 at 1360 cm⁻¹ of Si—CH₂—Si is shown with an absorbance of zero.

Referring to curve 18 in FIG. 1, the spectrum displays a strong Si—O absorption band 36 at 975-1200 cm⁻¹ with an absorbance of 0.485, a Si—CH₃ absorption peak 38 at 1273 cm⁻¹ with an absorbance of 0.11, a Si—Meₓ absorption peak 39 at 1412 cm−1 with an absorbance of 0.06, a Si—H absorption band 40 at 2173-2242 cm⁻¹ with an absorbance of 0.001, and C—H absorption peaks 42 and 44 at 2920-2972 cm⁻¹ with a respective absorbance of 0.002, and 0.028. The marked absorbance peak 46 at 1360 cm⁻¹ of Si—CH₂—Si is shown with an absorbance of 0.001.

Referring to curve 20 in FIG. 1, the spectrum displays a strong Si—O absorption band 50 at 975-1200 cm⁻¹ with an absorbance of 0.485, a Si—CH₃ absorption peak 52 at 1273 cm⁻¹ with an absorbance of 0.0875, a Si—Meₓ absorption peak 53 at 1412 cm−1 with an absorbance of 0.05, a Si—H absorption band 54 at 2173-2242 cm⁻¹ with an absorbance of 0.009, and C—H absorption peaks 56 and 58 at 2920-2972 cm⁻¹ with a respective absorbance of 0.009, and 0.025. The marked absorbance peak 60 at 1360 cm⁻¹ of Si—CH₂—Si is shown with an absorbance of 0.005.

The numerical data provided in the above paragraphs 21-24 was determined from measurements of waveforms 16, 18 and 20.

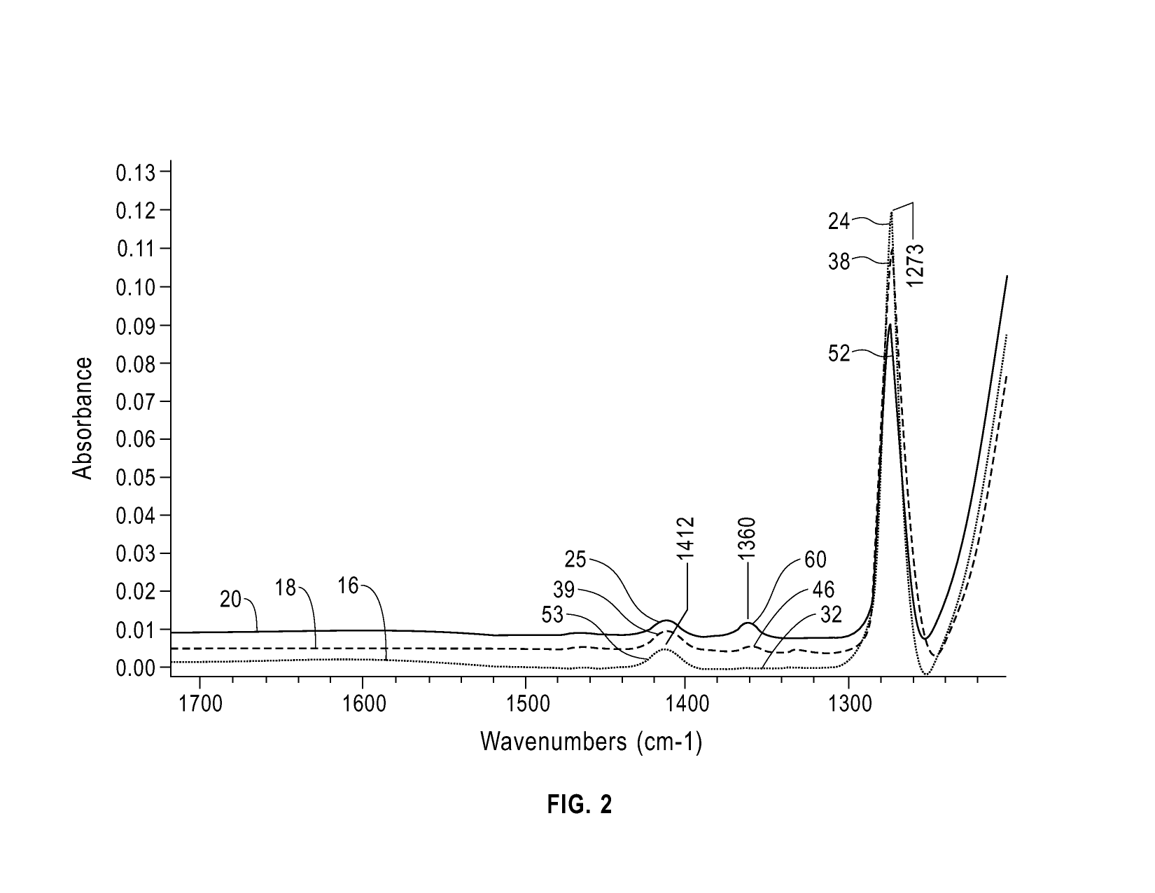

FIG. 2 shows an enlarged portion of FIG. 1 with changes in the scale of the abscissa and the ordinate. FIG. 2 shows the amplitude of absorbance peaks of curves 16, 18 and 20 at the same wave number. In FIG. 2, wave number 1360 corresponding to Si—CH₂—Si bonds shows curve 16 has an amplitude of 0.0, curve 18 has an amplitude of 0.0024 and curve 20 has an amplitude of 0.0048. Curve 20 has an amplitude increase of 100 percent over curve 18. This indicates an increase of 100 percent in Si—CH₂—Si bonds. It should also be noted that the low vibrational intensity of Si—CH₂—Si is due to the strong bonding of CH₂ to two Si atoms. Also in FIG. 2, wave number 1410 corresponding to Si—Meₓ bonds shows curve 16 absorption peak 25 has an amplitude of 0.0052, curve 18 absorption peak 39 has an amplitude of 0.0052 and curve 20 absorption peak 53 has an amplitude of 0.0047 which is a reduction of 9.6 percent. The 100 percent increase in Si—CH₂—Si improves the modulus of elasticity and hardness of the dielectric layer of the present invention via the inventive method. The inventive method results in a 20.5 percent removal or reduction of Si—CH₃ bonds

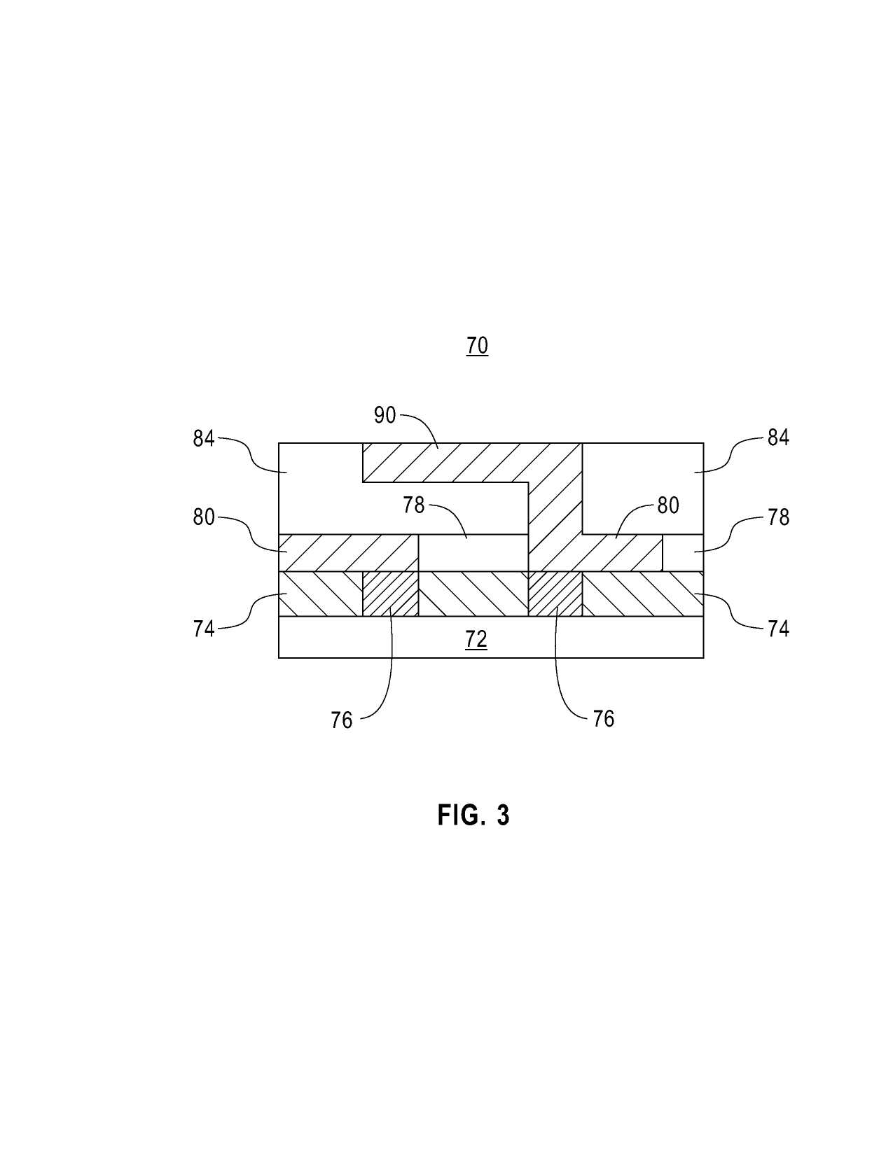

FIG. 3 shows a semiconductor integrated circuit with interconnection wiring which include the inventive porous SiCOH dielectric material. It should be noted that the integrated circuit shown in FIG. 3 is an illustrative embodiment of the present invention, and that there are many other devices or embodiments which may be formed by the present inventive methods or by incorporating the inventive dielectric material.

In FIG. 3, an integrated circuit 70 built on a silicon substrate 72 is shown. Substrate 72 may contain semiconductor devices such as field effect transistors and other devices (not shown). On top of the silicon substrate 72, an insulating material layer 74 is first formed with a first region of metal 76 embedded therein for connection to semiconductor devices in substrate 72. After a chemical mechanical polishing (CMP) process is conducted on the first region of metal 76, a stable ultra low k porous SiCOH dielectric film 78 of the present invention is deposited on top of the first layer of insulating layer 74 and the first region of metal 76. The first layer of insulating material 74 may be suitably formed of silicon oxide, silicon nitride, doped varieties of these materials, or any other suitable insulating materials. The stable ultra low k porous SiCOH dielectric film 78 is then patterned in a photolithography process followed by etching and a conductor layer 80 is deposited thereon. After a CMP process on the first conductor layer 80 is carried out, a second layer of the inventive SiCOH film 84 is deposited by a PECVD process overlying first SiCOH dielectric film 78 and first conductor layer 80. First conductor layer 80 may be a metallic material such as aluminum, copper or alloys thereof or a nonmetallic conductive material such as a metal nitride or polysilicon. First conductor 80 is in electrical communication with the first region of metal 76. The structure of FIG. 3 is intended to show a general structure embodiment of patterned metal conductor 80 within a stable ultra low k porous SiCOH dielectric film 78 of the present invention, 78 or 80. Other patterned wiring embodiments and other methods to form these embodiments may also be used within the present invention.

While there has been described and illustrated a method comprising a plasma enhanced chemical vapor deposition (PECVD) process utilizing a first and second precursor and an energy post treatment of ultra violet radiation, a porous SiCOH dielectric material having a tri-dimensional random covalently bond network of Si—O, Si—C, Si—(CH₂)ₙ—Si where n is an integer 1, 2 or 3, C—O, Si—H, and C—H bonds, and one of a dielectric constant k in the range from 2.2 to 2.3 and a modulus of elasticity greater than or equal to 5 GPa, a k in the range from 2.3 to 2.4 and a modulus of elasticity greater than 6 GPa, a k in the range from 2.4 to 2.5 and a modulus of elasticity greater than 7.8 GPa, and a k in the range from 2.5 to 2.55 and a modulus of elasticity in the range from 9 to 15 GPa and a semiconductor integrated circuit comprising an interconnect wiring having porous SiCOH dielectric material as described above, it will be apparent to those skilled in the art that modifications and variations are possible without deviating from the broad scope of the invention which shall be limited solely by the scope of the claims appended hereto.

What is claimed is:

1. A method for forming an ultra low k dielectric layer comprising:
selecting a plasma enhanced chemical vapor deposition reactor;
placing a substrate in said reactor;
introducing a gas mixture flow into said reactor; said gas mixture comprising an inert carrier gas, a first precursor gas comprising at least one of a carbosilane and alkoxycarbosilane molecules comprising atoms of Si, C, O and H and containing the group Si—(CH₂)ₙ—Si where n is an integer 1, 2 or 3 and a second precursor gas containing the group Si—R* comprising atoms of Si, C, O and H and where R* is an embedded organic porogen;
heating said substrate to a temperature above 100° C.;
forming a deposited layer by applying high frequency radio frequency power in said reactor;
after a period of time terminating said high frequency radio frequency power in said reactor; and
applying to said deposited layer an energy post treatment comprising ultra violet (UV) radiation to drive out said embedded organic porogen, create porosity in said deposited layer and increase cross-linking in said deposited layer.

2. The method of claim 1 wherein said applying an energy post treatment includes irradiating with said ultraviolet radiation for a time period to increase Si—(CH₂)ₙ—Si cross linking bonds in said deposited layer to form a dielectric layer having a dielectric constant in the range from 2.2 to 2.3 and a modulus of elasticity greater than or equal to 5.

3. The method of claim 1 wherein said applying an energy post treatment includes irradiating with said ultraviolet radiation for a time period to increase Si—(CH₂)ₙ—Si cross linking bonds in said deposited layer to form a dielectric layer having a dielectric constant in the range from 2.3 to 2.4 and a modulus of elasticity greater than or equal to 6.

4. The method of claim 1 wherein said applying an energy post treatment includes irradiating with said ultraviolet radiation for a time period to increase Si—(CH₂)ₙ—Si cross linking bonds in said deposited layer to form a dielectric layer having a dielectric constant in the range from 2.4 to 2.5 and a modulus of elasticity greater than or equal to 7.8 GPa.

5. The method of claim 1 wherein said applying an energy post treatment includes irradiating with said ultraviolet radiation for a time period to increase Si—(CH₂)ₙ—Si cross linking bonds in said deposited layer to form a dielectric layer having a dielectric constant in the range from 2.5 to 2.55 and a modulus of elasticity in the range from 9 to 15 GPa.

6. The method of claim 1 wherein said applying an energy post treatment includes irradiating for a time period to cause adjacent Si—CH₃ chemical bonds in said deposited layer to change to Si—(CH₂)ₙ—Si bonds to increase a modulus of elasticity of said deposited layer.

7. The method of claim 1 wherein said first precursor gas is selected from the group consisting of bis(triethoxysilyl)methane, bis(diethoxymethylsilyl)methane, bis(trimethoxysilyl)methane and bis(dimethoxymethylsilyl)methane.

8. The method of claim 1 wherein said second precursor gas comprises a Si based precursor with at least one group bonded to Si selected from group consisting of n-butyl, n-propyl, iso-propyl, vinyl, and alkyl, alkene and alkyne groups containing 2, 3 or 4 carbon atoms.

9. The method of claim 8 wherein said at least one group bonded to Si comprises one or more oxygen atoms.

10. The method of claim 1 wherein said second precursor gas comprises a Si based precursor with at least one group bonded to Si selected from a group comprising 5 to 10 carbon atoms bonded in a linear, branched, monocyclic or bicyclic structure.

11. The method of claim 10 wherein said at least one group bonded to Si comprises one or more oxygen atoms.

12. The method of claim 1 wherein said second precursor gas comprises a Si based precursor with at least one group bonded to Si selected from the group consisting of methoxy, ethoxy, methyl and ethyl.

13. The method of claim 1 wherein said deposited layer comprises a tri-dimensional random covalently bonded network of Si, C, O and H.

14. The method of claim 1 further including introducing a gas selected from the group consisting of a reactive oxidant gas, and an oxygenated hydrocarbon gas into said reactor.

15. The method of claim 1 wherein said oxidant gas is selected from the group consisting of O₂, N₂O, CO₂, and combinations thereof.

16. A porous SiCOH dielectric material having a tri-dimensional random covalently bond network of Si—O, Si—C, Si—(CH₂)ₙ—Si where n is an integer 1, 2 or 3, C—O, Si—H, and C—H bonds, a dielectric constant k in the range from 2.2 to 2.3 and a modulus of elasticity greater than or equal to 5 GPa.

17. The porous SiCOH dielectric material of claim 16 wherein said porous SiCOH dielectric material has a dielectric constant k in a new range from 2.3 to 2.4 and a new modulus of elasticity greater than or equal to 6 GPa.

18. The porous SiCOH dielectric material of claim 16 wherein said porous SiCOH dielectric material has a dielectric constant k in a new range from 2.4 to 2.5 and a new modulus of elasticity greater than or equal to 7.8 GPa.

19. The porous SiCOH dielectric material of claim 16 wherein said porous SiCOH dielectric material has a dielectric constant k in a new range from 2.5 to 2.55 and a new modulus of elasticity in the range from 9 to 15 GPa.

20. A semiconductor integrated circuit comprising an interconnect wiring having a porous SiCOH dielectric material having a tri-dimensional random covalently bond network of Si—O, Si—C, Si—(CH₂)ₙ—Si where n is an integer 1, 2 or 3, C—O, Si—H, and C—H bonds having a dielectric constant k in the range from 2.2 to 2.3 and a modulus of elasticity greater than or equal to 5 GPa.

21. The semiconductor integrated circuit of claim 20 wherein said porous SiCOH dielectric material has a dielectric constant k in a new range from 2.3 to 2.4 and a new modulus of elasticity greater than or equal to 6 GPa.

22. The semiconductor integrated circuit of claim 20 wherein said porous SiCOH dielectric material has a dielectric constant k in a new range from 2.4 to 2.5 and a new modulus of elasticity greater than or equal to 7.8 GPa.

23. The semiconductor integrated circuit of claim 20 wherein said porous SiCOH dielectric material has a dielectric constant k in a new range from 2.5 to 2.55 and a new modulus of elasticity in the range from 9 GPa to 15 GPa.
